(19) United States
(12) Patent Application Publication
(10) Pub. No.: US 2024/0222299 A1
(43) Pub. Date: Jul. 4, 2024

(54) SEMICONDUCTOR PACKAGE AND METHOD FOR MANUFACTURING THE SAME

(71) Applicant: SAMSUNG ELECTRONICS CO., LTD., Suwon-si (KR)

(72) Inventors: Hwan Young CHOI, Suwon-si (KR); Seok Hyun Lee, Suwon-si (KR); Cheol Kim, Suwon-si (KR); Seok Geun Ahn, Suwon-si (KR)

(21) Appl. No.: 18/402,021

(22) Filed: Jan. 2, 2024

(30) Foreign Application Priority Data
Jan. 2, 2023 (KR) 10-2023-0000410

(51) Int. Cl. H01L 23/00; H01L 23/48; H01L 23/522

(52) U.S. Cl. CPC H01L 24/08; H01L 23/481; H01L 23/5226; H01L 24/05; H01L 24/80; H01L 2224/05017; H01L 2224/05147; H01L 2224/05644; H01L 2224/08145; H01L 2224/80379; H01L 2224/80895; H01L 2224/80896

(57) ABSTRACT

A semiconductor package comprises a first semiconductor chip and a second semiconductor chip. The first semiconductor chip includes a first substrate, a first semiconductor device layer disposed on the first substrate, a first chip wiring layer disposed on the first semiconductor device layer, and a first bonding pad directly connected to the first chip wiring layer and that includes a first dishing formed thereon. The second semiconductor chip includes a second substrate, a first through-via that penetrates through the second substrate, and a second bonding pad directly connected to the first through-via and that includes a second dishing formed thereon. The first semiconductor chip and the second semiconductor chip are bonded to each other and the first bonding pad and the second bonding pad face each other, and a gold bonding layer fills the first dishing of the first bonding pad and the second dishing of the second bonding pad.

### CROSS-REFERENCE TO RELATED APPLICATION

This application claims priority under 35 U.S.C. 119 from Korean Patent Application No. 10-2023-0000410, filed on Jan. 2, 2023 in the Korean Intellectual Property Office, the contents of which are herein incorporated by reference in their entirety.

### TECHNICAL FIELD

Embodiments of the present disclosure are directed to a semiconductor package and a method for manufacturing the same.

### DISCUSSION OF THE RELATED ART

A semiconductor package is being developed that enables a semiconductor chip that has more diverse functions and high reliability to be efficiently manufactured. Further, to mount a larger number of semiconductor chips in the same area, a stack type semiconductor package in which a plurality of semiconductor chips are stacked on top of each other is proposed.

The semiconductor package has a structure in which different types of semiconductor chips are vertically stacked. To implement a semiconductor package having such a structure, a semiconductor package is being developed in which the semiconductor chips include through silicon vias (TSVs) and are stacked in a vertical direction.

In this regard, when vertically stacking multiple semiconductor chips, a hybrid copper bonding scheme is used for bonding between semiconductors. In this regard, deterioration of bonding quality can occur due to expansion of a copper pad (Cu pad) due to a temperature applied during a bonding process, and an oxide film that forms on a surface of the pad. Therefore, research to improve reliability of a hybrid copper bonding is in progress.

### SUMMARY

Embodiments of the present disclosure provide a semiconductor package with increased reliability.

Embodiments of the present disclosure also provide a method for manufacturing a semiconductor package with increased reliability.

According to an embodiment of the present disclosure, there is provided a semiconductor package that includes a first semiconductor chip and a second semiconductor chip. The first semiconductor chip includes a first substrate, a first semiconductor device layer disposed on the first substrate, a first chip wiring layer disposed on the first semiconductor device layer, and a first bonding pad directly connected to the first chip wiring layer and that includes a first dishing formed thereon. The second semiconductor chip includes a second substrate, a first through-via that penetrates through the second substrate, and a second bonding pad directly connected to the first through-via and that includes a second dishing formed thereon. The first semiconductor chip and the second semiconductor chip are bonded to each other so that the first bonding pad and the second bonding pad face each other, and a gold bonding layer fills the first dishing of the first bonding pad and the second dishing of the second bonding pad.

According to an embodiment of the present disclosure, there is provided a semiconductor package that includes a first semiconductor chip and a second semiconductor chip. The first semiconductor chip includes a first substrate, a first semiconductor device layer disposed on the first substrate, a first chip wiring layer disposed on the first semiconductor device layer, a first bonding insulating film disposed on the first chip wiring layer, a first bonding pad that includes a first dishing formed thereon, where at least a portion of a side surface of the first bonding pad is surrounded by the first bonding insulating film, a first gold layer that fills the first dishing, and a first through-via that penetrates through the first substrate and is connected to the first bonding pad. The second semiconductor chip includes a second substrate, a second bonding insulating film disposed on the second substrate, a second bonding pad that includes a second dishing formed thereon, where at least a portion of a side surface of the second bonding pad is surrounded by the second bonding insulating film, a second gold layer that fills the second dishing, and a second through-via that penetrates through the second substrate and is connected to the second bonding pad. The first semiconductor chip and the second semiconductor chip are bonded to each other so that the first bonding pad and the second bonding pad face each other, and the first gold layer and the second gold layer are bonded to each other.

According to an embodiment of the present disclosure, there is provided a method for manufacturing a semiconductor package. The method comprises providing the first semiconductor chip and the second semiconductor chip, where the first semiconductor chip includes a first bonding pad that includes a first dishing formed therein, a first bonding insulating film that surrounds at least a portion of a side surface of the first bonding pad, and a first gold layer that fills the first dishing, and the second semiconductor chip includes a second bonding pad that includes a second dishing formed therein, a second bonding insulating film that surrounds at least a portion of a side surface of the second bonding pad, and a second gold layer that fills the second dishing, bonding the first bonding insulating film and the second bonding insulating film to each other, applying heat to the first semiconductor chip and the second semiconductor chip to expand the first bonding pad and the second bonding pad and the first gold layer and the second gold layer, and bonding the first gold layer and the second gold layer to each other.

### BRIEF DESCRIPTION OF DRAWINGS

FIG. 1 to FIG. 5 illustrate portions of a semiconductor package according to some embodiments.

FIG. 6 illustrates a semiconductor package according to some embodiments.

FIG. 7 illustrates a semiconductor package according to some further embodiments.

FIG. 8 illustrates a semiconductor package according to some still further embodiments.

FIG. 9 illustrates a semiconductor package according to some still further embodiments.

FIG. 10 illustrates a semiconductor package according to some still further embodiments.

FIG. 11 is a flowchart of a method for manufacturing a semiconductor package according to some embodiments.

FIG. 12 is a flowchart of a process of providing a first semiconductor chip of FIG. 11.

FIG. 13 is a flowchart of a process of providing a second semiconductor chip of FIG. 11.

FIG. 14 to FIG. 20 illustrate intermediate structures of intermediate steps of a process of providing a first semiconductor chip of FIG. 12.

FIG. 21 to FIG. 27 illustrate intermediate structures of intermediate steps of a process of providing a second semiconductor chip of FIG. 13.

FIG. 28 and FIG. 29 illustrate intermediate structures of intermediate steps of a method for manufacturing a semiconductor package of FIG. 11.

### DETAILED DESCRIPTIONS

Hereinafter, a semiconductor package and a method for manufacturing the same according to some embodiments will be described with reference to the accompanying drawings.

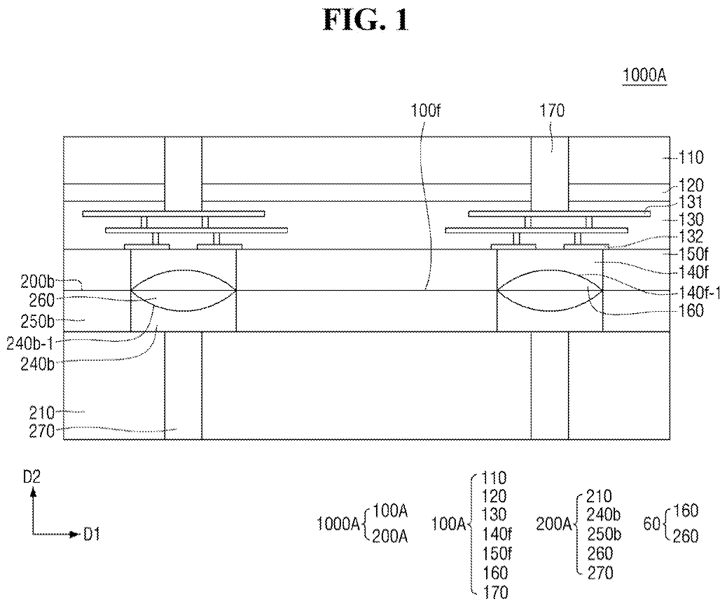

FIG. 1 to FIG. 5 illustrate portions of a semiconductor package according to some embodiments.

First, referring to FIG. 1, a semiconductor package 1000A according to some embodiments includes a semiconductor chip 100A, a semiconductor chip 200A, and a gold bonding layer (Au bonding layer) 60. FIG. 1 partially shows the semiconductor package 1000A in which a face surface 100f of the semiconductor chip 100A and a back surface 200b of the semiconductor chip 200A are bonded to each other in a hybrid bonding scheme. However, each of the semiconductor package 1000A, the semiconductor chip 100A, and the semiconductor chip 200A may further include other components than those shown in FIG. 1.

The semiconductor chip 100A and the semiconductor chip 200A may be of different types. For example, semiconductor chip 100A is a memory semiconductor chip, and the semiconductor chip 200A is a logic semiconductor chip. The memory semiconductor chip may be, for example, a volatile memory such as a DRAM (dynamic random access memory) or an SRAM (static random access memory). Alternatively, the memory semiconductor chip may be a non-volatile memory such as a flash memory, a PRAM (phase-change random access memory), an MRAM (magnetoresistive random access memory), an FeRAM (ferroelectric random access memory), or an RRAM (resistive random access memory). The logic semiconductor chip may be, for example, an application processor (AP) such as CPU (Central Processing Unit), a GPU (Graphic Processing Unit), an FPGA (Field-Programmable Gate Array), a digital signal processor, a cryptographic processor, a microprocessor, a microcontroller, an ASIC (Application-Specific IC), etc. However, embodiments of the present disclosure are not necessarily limited thereto.

Alternatively, each of the semiconductor chip 100A and the semiconductor chip 200A is a memory semiconductor chip. The memory semiconductor chip may be, for example, a volatile memory such as a DRAM (dynamic random access memory) or an SRAM (static random access memory). Alternatively, the memory semiconductor chip may be a non-volatile memory such as a flash memory, a PRAM (phase-change random access memory), an MRAM (magnetoresistive random access memory), an FeRAM (ferroelectric random access memory), or an RRAM (resistive random access memory). The semiconductor chip 200A may be, for example, a buffer semiconductor chip.

The semiconductor chip 100A includes a substrate 110, a semiconductor device layer 120, a chip wiring layer 130, a bonding insulating film 150f, a bonding pad 140f, and a gold layer 160. The semiconductor chip 100A includes one surface 100f and another surface that are opposite to each other. FIG. 1 shows a portion of the semiconductor chip 100A in which a reference numeral of the another surface of the semiconductor chip 100A is omitted. One surface 100f of the semiconductor chip 100A and the another surface thereof are opposite to each other in a second direction D2. In the second direction D2, the one surface 100f of the semiconductor chip 100A is a face surface of the semiconductor chip 100A, and the another surface of the semiconductor chip 100A is a back surface of the semiconductor chip 100A.

The semiconductor chip 100A is formed by sequentially stacking the substrate 110, the semiconductor device layer 120, the chip wiring layer 130, the bonding insulating film 150f, the bonding pad 140f, and the gold layer 160. Accordingly, in the semiconductor chip 100A, a layer in which the bonding insulating film 150f is disposed is a top portion of the semiconductor chip 100A, while a layer in which the substrate 110 is disposed is a bottom portion of the semiconductor chip 100A.

The substrate 110 is made of, for example, bulk silicon or SOI (silicon-on-insulator). The substrate 110 may be a silicon substrate, or may include a material other than silicon, including, for example, one or more of silicon germanium, indium antimonide, lead telluride compound, indium arsenide, indium phosphide, gallium arsenide or gallium antimonide. Alternatively, the substrate 110 includes a base substrate and an epitaxial layer formed on the base substrate.

The semiconductor device layer 120 is disposed on the substrate 110. The semiconductor device layer 120 includes various microelectronic devices, such as a MOSFET (metal-oxide-semiconductor field effect transistor) such as a CMOS transistor (a complementary metal-insulator-semiconductor transistor), a system LSI (large scale integration), a flash memory, a DRAM, an SRAM, an EEPROM, a PRAM, an MRAM, an RRAM, an image sensor such as a CIS (CMOS imaging sensor), a MEMS (micro-electro-mechanical system), an active device, a passive device, etc.

The chip wiring layer 130 is disposed on the semiconductor device layer 120. In some embodiments, the chip wiring layer 130 includes a wiring pattern 131 therein. The wiring pattern 131 includes a wiring stack that has a multilayer structure and a via that connects layers of the wiring stack to each other. An arrangement, the number of layers, and the number of the wiring patterns 131 are illustrative, and embodiments of the present disclosure are not necessarily limited thereto. At least one connective pad 132 that directly contacts the bonding pad 140f is formed on the uppermost portion of the chip wiring layer 130.

The semiconductor device layer 120 is electrically connected to the wiring pattern 131. The chip wiring layer 130 is electrically connected to the semiconductor device layer 120. In some embodiments, when a through-via 170 that penetrates through the substrate 110 to be connected to the bonding pad 140f is formed, the wiring pattern 131 electrically connects the through-via 170 and the bonding pad 140f to each other.

The wiring pattern 131 includes, for example, a conductive film and a barrier film. The conductive film of the wiring pattern 131 includes, for example, at least one of tungsten (W), aluminum (Al), or copper (Cu). However, embodiments of the present disclosure are not necessarily limited thereto. The barrier film of the wiring pattern 131 includes, for example, at least one of titanium (Ti), titanium nitride (TiN), tantalum (Ta), or tantalum nitride (TaN). However, embodiments of the present disclosure are not necessarily limited thereto.

In some embodiments, the semiconductor chip 100A includes the through-via 170 that penetrates through the substrate 110. For example, when another semiconductor chip is disposed on the another surface of the semiconductor chip 100A, that is, the back surface of the semiconductor chip 100A, and is connected to the semiconductor chip 100A, the through-via 170 that penetrates through the substrate 110 of the semiconductor chip 100A is formed. However, when the semiconductor chip 100A is located at the topmost level of a semiconductor package, and thus, no other semiconductor chip is disposed on the semiconductor chip 100A, the semiconductor chip 100A does not include the through-via 170.

The through-via 170 is formed to penetrate through the substrate 110. For example, the through-via 170 has a columnar shape that extends in the second direction D2. The through-via 170 is electrically connected to wiring pattern 131. For example, as shown in FIG. 1, the through-via 170 penetrates through the semiconductor device layer 120 and a portion of the chip wiring layer 130 to be electrically connected to the wiring pattern 131. Thus, the through-via 170 is connected to the bonding pad 140f.

The through-via 170 includes, for example, a barrier film formed as a columnar surface and a buried conductive layer that fills an inner space defined by the barrier film. The barrier film includes at least one of Ti, TiN, Ta, TaN, Ru, Co, Mn, WN, Ni, or NiB. However, embodiments of the present disclosure are not necessarily limited thereto. The buried conductive layer includes at least one of Cu, a Cu alloy such as CuSn, CuMg, CuNi, CuZn, CuPd, CuAu, CuRe, or CuW, W, a W alloy, Ni, Ru, or Co. However, embodiments of the present disclosure are not necessarily limited thereto. For example, in some embodiments, an insulating film is interposed between the substrate 110 and the through-via 170. The insulating film includes at least one of an oxide film, a nitride film, a carbide film, a polymer, or a combination thereof. However, embodiments of the present disclosure are not necessarily limited thereto.

The bonding insulating film 150f is disposed on the chip wiring layer 130. In some embodiments, the bonding insulating film 150f includes an insulating material such as silicon oxide. For example, the bonding insulating film 150f includes at least one of SiO, SiN, SiCN, SiOC, SiON, or SiOCN. However, embodiments of the present disclosure are not necessarily limited thereto.

The bonding pad 140f includes a metal, such as copper (Cu). The bonding insulating film 150f surrounds at least a portion of a side surface of the bonding pad 140f. Thus, the bonding insulating film 150f prevents the bonding pad 140f from being externally exposed and thus protects the bonding pad 140f. The bonding pad 140f is directly connected to the chip wiring layer 130.

A dishing 140f-1 is formed in the bonding pad 140f. The dishing 140f-1 is a cavity that is inwardly recessed from an upper surface of the bonding pad 140f. For example, the upper surface of the bonding pad 140f is opposite to a lower surface of the bonding pad 140f in the second direction D2. The lower surface of the bonding pad 140f directly contacts the chip wiring layer 130. The dishing 140f-1 is formed by performing a CMP (chemical mechanical polishing) process on the upper surface of the bonding pad 140f such that the bonding pad 140f is inwardly recessed from the upper surface of the bonding pad 140f.

The gold layer 160 is disposed in the dishing 140f-1 and fills at least a portion of the dishing 140f-1. The gold layer 160 is formed by injecting gold (Au) into the dishing 140f-1 using a sputtering process to fill at least a portion of the dishing 140f-1. A portion of the one surface 100f of the semiconductor chip 100A is not covered with the bonding insulating film 150f and the gold layer 160 and is exposed.

The semiconductor chip 200A includes a substrate 210, a through-via 270, a bonding insulating film 250b, a bonding pad 240b, and a gold layer 260. The semiconductor chip 200A includes one surface 200b and another surface that are opposite to each other. FIG. 1 shows a portion of the semiconductor chip 200A such that a reference numeral of the another surface of the semiconductor chip 200A is omitted. The one surface 200b and the another surface of the semiconductor chip 200A are opposite to each other in the second direction D2. In the second direction D2, the one surface 200b of the semiconductor chip 200A is a back surface of the semiconductor chip 200A, and the another surface of the semiconductor chip 200A is a face surface of the semiconductor chip 200A.

The semiconductor chip 200A is formed by sequentially stacking the substrate 210, the bonding insulating film 250b, the bonding pad 240b, and the gold layer 260. Accordingly, in the semiconductor chip 200A, a layer in which the bonding insulating film 250b is disposed is a top portion of the semiconductor chip 200A, while a layer in which the substrate 210 is disposed is a bottom portion of the semiconductor chip 200A.

The substrate 210 is made of, for example, bulk silicon or SOI (silicon-on-insulator). The substrate 210 may be a silicon substrate, or may include a material other than silicon, including, for example, at least one of silicon germanium, indium antimonide, lead telluride compound, indium arsenide, indium phosphide, gallium arsenide or gallium antimonide. Alternatively, the substrate 210 has a base substrate and an epitaxial layer formed on the base substrate.

The through-via 270 is formed to extend through the substrate 210. For example, the through-via 270 has a columnar shape that extends in the second direction D2. The through-via 270 is directly connected to the bonding pad 250b.

The through-via 270 includes, for example, a barrier film formed as a columnar surface and a buried conductive layer that fills an inner space defined by the barrier film. The barrier film includes at least one of Ti, TiN, Ta, TaN, Ru, Co, Mn, WN, Ni, or NiB. However, embodiments of the present disclosure are not necessarily limited thereto. The buried conductive layer includes at least one of Cu, a Cu alloy such as CuSn, CuMg, CuNi, CuZn, CuPd, CuAu, CuRe, or CuW, W, a W alloy, Ni, Ru, or Co. However, embodiments of the present disclosure are not necessarily limited thereto. For example, in an embodiment, an insulating film is interposed between the substrate 210 and the through-via 270. The insulating film includes one of an oxide film, a nitride film, a carbide film, a polymer, or a combination thereof. However, embodiments of the present disclosure are not necessarily limited thereto.

The bonding insulating film 250b is disposed on the substrate 210. In some embodiments, the bonding insulating film 250b includes an insulating material such as silicon oxide. For example, the bonding insulating film 250b includes at least one of SiO, SiN, SiCN, SiOC, SiON, or SiOCN. However, embodiments of the present disclosure are not necessarily limited thereto.

The bonding pad 240b includes the same metal as the bonding pad 140f. For example, the bonding pad 240b includes copper (Cu). The bonding insulating film 250b surrounds at least a portion of a side surface of the bonding pad 240b. Thus, the bonding insulating film 250b prevents the bonding pad 240b from being externally exposed and thus protects the bonding pad 240b. The bonding pad 240b is directly connected to the through-via 270.

A dishing 240b-1 is formed in the bonding pad 240b. The dishing 240b-1 is a cavity that is inwardly recessed from an upper surface of the bonding pad 240b. The upper surface of the bonding pad 240b is a surface opposite to the lower surface of the bonding pad 240b. The lower surface of the bonding pad 240b directly contacts the through-via 270. The dishing 240b-1 is formed by performing a CMP (chemical mechanical polishing) process on the upper surface of the bonding pad 240b such that the bonding pad 240b inwardly recessed from the upper surface of the bonding pad 240b.

The gold layer 260 is disposed in the dishing 240b-1 and fills at least a portion of the dishing 240b-1. The gold layer 260 is formed by injecting gold (Au) into the dishing 240b-1 via a sputtering process to fill at least a portion of the dishing 240b-1. A portion of one surface 200b of the semiconductor chip 200A is not covered with the bonding insulating film 250b and the gold layer 260 and is exposed.

The semiconductor chip 100A and the semiconductor chip 200A are bonded to each other in a hybrid bonding scheme by an annealing process. For example, the bonding insulating film 150f and the bonding insulating film 250b directly contact and are bonded to each other through a high-temperature annealing process, and have a strong bonding strength therebetween due to a covalent bond between silicon and oxygen. For example, the bonding insulating film 150f and the bonding insulating film 250b are bonded to each other in a dielectric-dielectric bonding scheme.

Further, the bonding pad 140f and the bonding pad 240b are bonded to each other using a material, such as gold (Au), through a high-temperature annealing process. When the semiconductor chip 100A and the semiconductor chip 200A are bonded to each other, the bonding pad 140f and the bonding pad 240b face each other. A space between the dishing 140f-1 of the bonding pad 140f and the dishing 240b-1 of the bonding pad 240b is filled with the gold bonding layer 60 formed by fusing the gold layer 160 and the gold layer 260 to each other.

In this way, when the semiconductor chip 100A and the semiconductor chip 200A are bonded to each other in a hybrid bonding scheme by an annealing process, the bonding pad 140f and the bonding pad 240b are not directly bonded to each other in a copper (Cu)-copper (Cu) bonding scheme, but the gold layer 160 and the gold layer 260 are directly bonded to each other such that the semiconductor chip 100A and the semiconductor chip 200A are bonded to each other by the gold (Au). As a result, a phenomenon in which a copper oxide forms on the upper surface of bonding pads 140f and 240b that include copper (Cu) is prevented, and thus, a deterioration of bonding quality between the bonding pads 140f and 240b can be suppressed.

Further, gold (Au), which has a smaller thermal expansion coefficient than copper (Cu), is disposed in each of the dishing 140f-1 of the bonding pad 140f and the dishing 240b-1 of the bonding pad 240b, such that the semiconductor chip 100A and the semiconductor chip 200A are bonded to each other when the gold layers 160 and 260 are bonded to each other. Thus, a standard dimension of each of the dishing 140f-1 and the dishing 240b-1 respectively formed in the upper surfaces of the bonding pads 140f and 240b can be more easily managed. For example, the standard dimension of each of the dishing 140f-1 and the dishing 240b-1 refers to a target depth of each of the dishing 140f-1 and the dishing 240b-1.

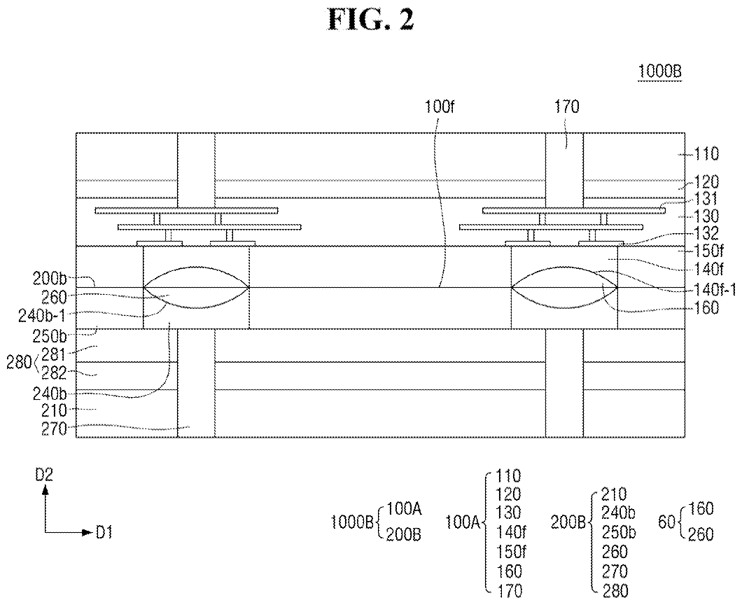

Referring to FIG. 2, a semiconductor package 1000B according to some embodiments include the semiconductor chip 100A, a semiconductor chip 200B, and the gold bonding layer 60. Hereinafter, descriptions that duplicate the above descriptions are omitted, and the following descriptions focus on differences.

In some embodiments, a buffer insulating film 280 is formed on a back surface of the semiconductor chip 200B. The buffer insulating film 280 includes an oxide film 282 and a nitride film 281 that are sequentially stacked. The through-via 270 extends through the buffer insulating film 280. An upper end of the buffer insulating film 280 directly contacts the bonding pad 240b. The bonding insulating film 250b is disposed on the buffer insulating film 280, and the bonding insulating film 250b is formed on the nitride film 281. The buffer insulating film 280 surrounds a portion of the side surface of the through-via 270 and thus protects the through-via 270. Further, the buffer insulating film 280 supports the bonding pad 240b and the bonding insulating film 250b.

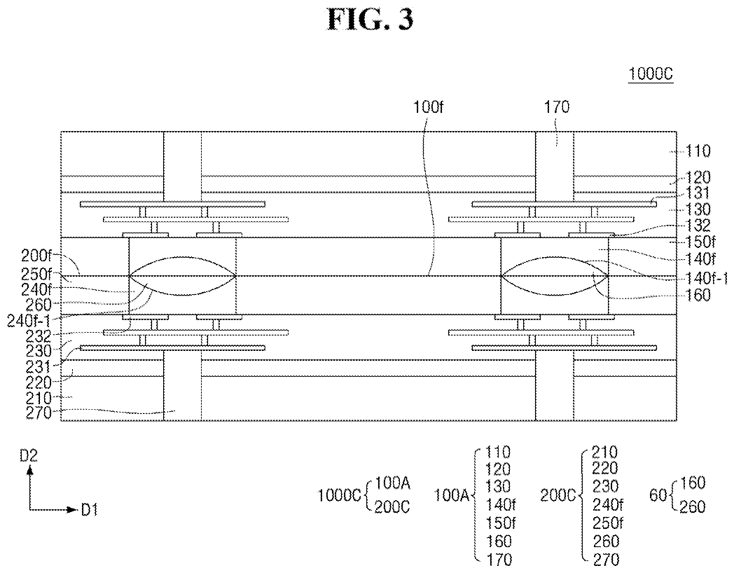

Referring to FIG. 3, a semiconductor package 1000C according to some embodiments includes the semiconductor chip 100A, a semiconductor chip 200C, and the gold bonding layer 60. FIG. 3 partially shows the semiconductor package 1000C in which the semiconductor chip 100A and the semiconductor chip 200C are bonded to each other in a hybrid bonding scheme. However, each of the semiconductor package 1000C, the semiconductor chip 100A, and the semiconductor chip 200C may further include components other than those shown in FIG. 3. Hereinafter, descriptions that duplicate the above descriptions are omitted, and the following descriptions focus on differences.

FIG. 3 shows a portion of the face surface 200f of the semiconductor chip 200C and the face surface 100f of the semiconductor chip 100A that are bonded to each other. The semiconductor chip 200C includes the substrate 210, a semiconductor device layer 220, a chip wiring layer 230, a bonding insulating film 250f, a bonding pad 240f, and the gold layer 260.

The semiconductor chip 200C is formed by sequentially stacking the substrate 210, the semiconductor device layer 220, the chip wiring layer 230, the bonding insulating film 250f, the bonding pad 240f, and the gold layer 260. Accordingly, in the semiconductor chip 200C, a layer in which the bonding insulating film 250f is disposed is a top portion of the semiconductor chip 200C, while a layer in which the substrate 210 is disposed is a bottom portion of the semiconductor chip 200C.

The semiconductor device layer 220, the chip wiring layer 230, a wiring pattern 231 and a connective pad 232 included in the chip wiring layer 230, the bonding pad 240f, and a dishing 240f-1 formed in the bonding pad 240f of the semiconductor chip 200C are respectively have the same configurations as those of and may respectively perform the same roles as those of the semiconductor device layer 120, the chip wiring layer 130, the wiring pattern 131, the connective pad 132, the bonding pad 140f, and the dishing 140f-1 of the semiconductor chip 100A corresponding thereto.

As shown in FIG. 3, when the face surface 100f of the semiconductor chip 100A and the face surface 200f of the semiconductor chip 200C are bonded to each other in a hybrid bonding scheme, the bonding insulating film 150f and the bonding insulating film 250f directly contact and are bonded to each other by a high-temperature annealing process, and have a strong bonding strength therebetween due to a covalent bond between silicon and oxygen. For example, the bonding insulating film 150f and the bonding insulating film 250f are bonded to each other in a dielectric-dielectric bonding scheme.

Further, the bonding pad 140f and the bonding pad 240f are bonded to each other by a material, such as gold (Au), by a high-temperature annealing process. When the semiconductor chip 100A and the semiconductor chip 200C are bonded to each other, the bonding pad 140f and the bonding pad 240f face each other, and a space between the dishing 140f-1 of the bonding pad 140f and the dishing 240f-1 of the bonding pad 240f is filled with the gold bonding layer 60 formed by fusing the gold layer 160 and the gold layer 260 to each other.

In this way, when the semiconductor chip 100A and the semiconductor chip 200C are bonded to each other in a hybrid bonding scheme by an annealing process, the bonding pad 140f and the bonding pad 240f are not directly bonded to each other in a copper (Cu)-copper (Cu) bonding scheme, but the gold layer 160 and the gold layer 260 are directly bonded to each other such that the semiconductor chip 100A and the semiconductor chip 200C are bonded to each other by the gold (Au). As a result, a phenomenon in which a copper oxide forms on the upper surface of bonding pads 140f and 240f that include copper (Cu) is prevented, which suppresses deterioration of bonding quality between the bonding pads 140f and 240f.

Further, gold (Au), which has a smaller thermal expansion coefficient than copper (Cu), is disposed on each of the dishing 140f-1 of the bonding pad 140f and the dishing 240f-1 of the bonding pad 240f, such that the semiconductor chip 100A and the semiconductor chip 200C are bonded to each other when the gold layers 160 and 260 are bonded to each other. Thus, a standard dimension of each of the dishing 140f-1 and the dishing 240f-1 respectively formed in the upper surfaces of the bonding pads 140f and 240f can be more easily managed. For example, the standard dimension of each of the dishing 140f-1 and the dishing 240f-1 refers to a target depth of each of the dishing 140f-1 and the dishing 240f-1.

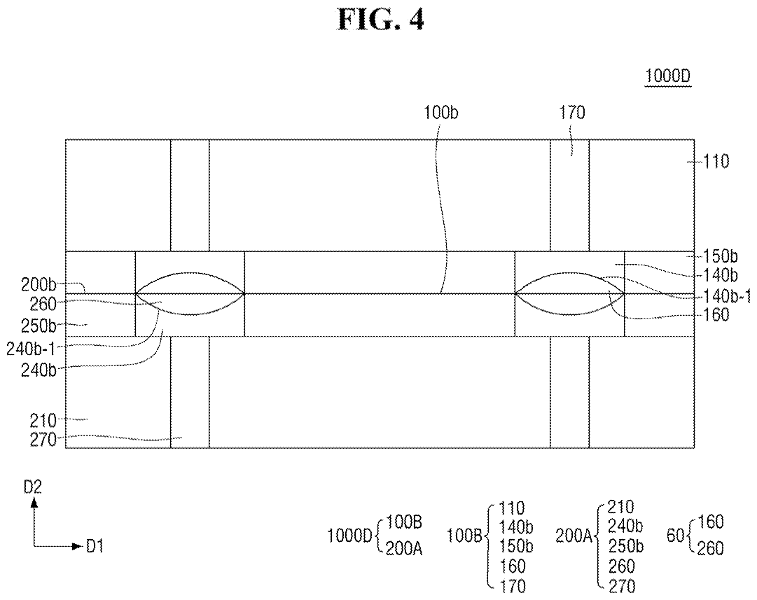

Referring to FIG. 4, a semiconductor package 1000D according to some embodiments may include a semiconductor chip 100B, the semiconductor chip 200A, and the gold bonding layer 60. FIG. 4 partially shows the semiconductor package 1000D in which the semiconductor chip 100B and the semiconductor chip 200A are bonded to each other in a hybrid bonding scheme. However, each of the semiconductor package 1000D, the semiconductor chip 100B, and the semiconductor chip 200A may further include components other than those shown in FIG. 3. Hereinafter, descriptions that duplicate the above descriptions are omitted, and the following descriptions focus on differences.

FIG. 4 shows a portion of a back surface 100b of the semiconductor chip 100B and the back surface 200b of the semiconductor chip 200A that are bonded to each other. The semiconductor chip 100B includes the substrate 110, a bonding insulating film 150b, a bonding pad 140b, and the gold layer 160.

The semiconductor chip 100B is formed by sequentially stacking the substrate 110, the bonding insulating film 150b, the bonding pad 140b, and the gold layer 160. Accordingly, in the semiconductor chip 100B, a layer in which the bonding insulating film 150b is disposed is a top portion of the semiconductor chip 100B, while a layer in which the substrate 110 is disposed is a bottom portion of the semiconductor chip 100B.

The bonding insulating film 150b, the bonding pad 140b, and a dishing 140b-1 formed in the bonding pad 140b of the semiconductor chip 100B respectively have the same configurations as those of and respectively perform the same roles as those of the bonding insulating film 250b, the bonding pad 240b, and the dishing 240b-1 of the semiconductor chip 200A corresponding thereto.

As shown in FIG. 4, when the back surface 100b of the semiconductor chip 100B and the back surface 200b of the semiconductor chip 200A are bonded to each other in a hybrid bonding scheme, the bonding insulating film 150b and the bonding insulating film 250b directly contact and are bonded to each other by a high-temperature annealing process, and have a strong bonding strength therebetween due to a covalent bond between silicon and oxygen. For example, the bonding insulating film 150b and the bonding insulating film 250b are bonded to each other in a dielectric-dielectric bonding scheme.

Further, the bonding pad 140f and the bonding pad 240b are bonded to each other by a material, such as gold (Au), by a high-temperature annealing process. When the semiconductor chip 100B and the semiconductor chip 200A are bonded to each other, the bonding pad 140b and the bonding pad 240b face each other, and a space between the dishing 140b-1 of the bonding pad 140b and the dishing 240b-1 of the bonding pad 240b is filled with the gold bonding layer 60 formed by fusing the gold layer 160 and the gold layer 260 to each other.

In this way, when the semiconductor chip 100B and the semiconductor chip 200A are bonded to each other in a hybrid bonding scheme by an annealing process, the bonding pad 140b and the bonding pad 240b are not directly bonded to each other in a copper (Cu)-copper (Cu) bonding scheme, but the gold layer 160 and the gold layer 260 are directly bonded to each other such that the semiconductor chip 100B and the semiconductor chip 200A are bonded to each other by the gold (Au). As a result, a phenomenon in which a copper oxide forms on the upper surface of bonding pads 140b and 240b that include copper (Cu) is prevented, which suppresses deterioration of the bonding quality between the bonding pads 140b and 240b.

Further, gold (Au), which has a smaller thermal expansion coefficient than copper (Cu), is disposed in each of the dishing 140b-1 of the bonding pad 140b and the dishing 240b-1 of the bonding pad 240b, such that the semiconductor chip 100B and the semiconductor chip 200A are bonded to each other when the gold layers 160 and 260 are bonded to each other. Thus, a standard dimension of each of the dishing 140b-1 and the dishing 240b-1 respectively formed in the upper surfaces of the bonding pads 140b and 240b can be more easily managed. For example, the standard dimension of each of the dishing 140b-1 and the dishing 240b-1 refers to a target depth of each of the dishing 140b-1 and the dishing 240b-1.

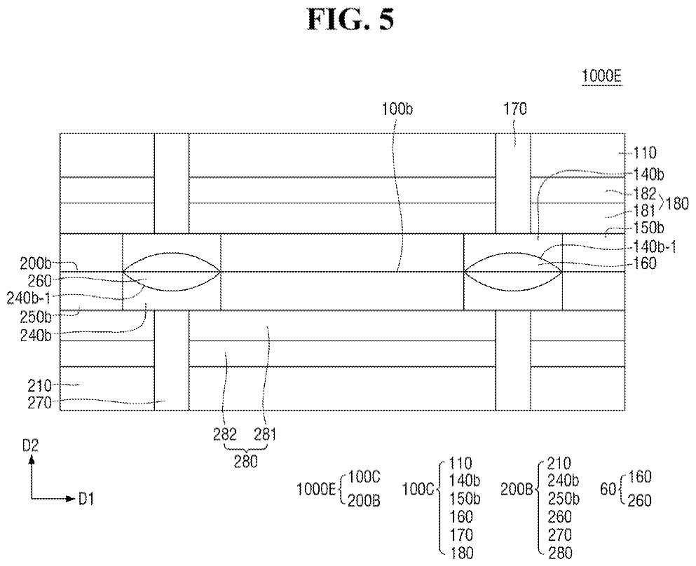

Referring to FIG. 5, a semiconductor package 1000E according to some embodiments includes a semiconductor chip 100C, the semiconductor chip 200B, and the gold bonding layer 60. Hereinafter, descriptions that duplicate the above descriptions are omitted, and the following descriptions focus on differences.

In some embodiments, a buffer insulating film 180 is formed on a back surface of the semiconductor chip 100C. The buffer insulating film 180 includes an oxide film 182 and a nitride film 181 that are sequentially stacked. The through-via 170 extends through the buffer insulating film 180, and an upper end of the buffer insulating film 180 directly contacts the bonding pad 140b. The bonding insulating film 150b is disposed on the buffer insulating film 180, and the bonding insulating film 150b is formed on the nitride film 181. The buffer insulating film 180 surrounds a portion of a side surface of the through-via 170 and protects the through-via 170. Further, the buffer insulating film 180 supports the bonding pad 140b and the bonding insulating film 150b.

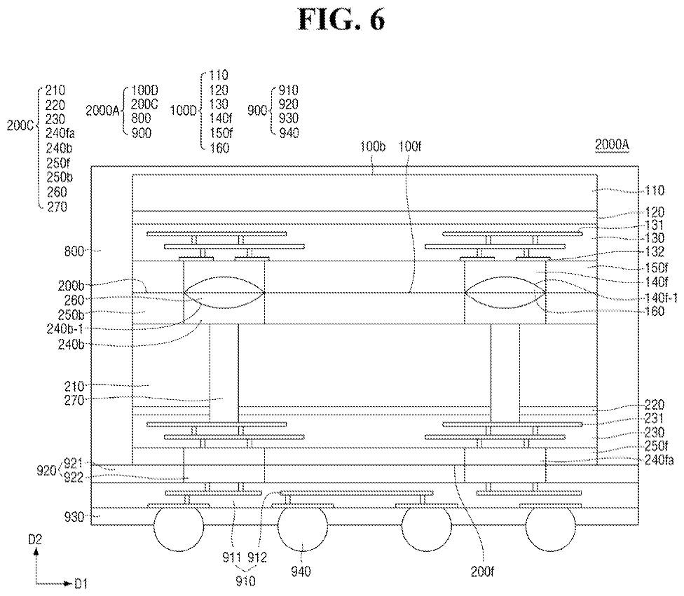

FIG. 6 illustrates a semiconductor package according to some embodiments.

Referring to FIG. 6, a semiconductor package 2000A according to some embodiments includes a semiconductor chip 100D, the semiconductor chip 200C, a mold film 800, and a redistribution substrate 900. Hereinafter, descriptions that duplicate the above descriptions are omitted, and the following descriptions focus on differences.

The semiconductor chip 100D includes the substrate 110, the semiconductor device layer 120, the chip wiring layer 130, the bonding pad 140f, the bonding insulating film 150f, and the gold layer 160. The semiconductor chip 100D constitutes a top portion of the semiconductor package 2000A, and does not include the through-via 170, shown in FIG. 1, that penetrates through the substrate 110. The back surface 100b of the semiconductor chip 100D faces an upper surface of the mold film 800. The face surface 100f of the semiconductor chip 100D is bonded to the back surface 200b of the semiconductor chip 200C.

The semiconductor chip 200C includes the substrate 210, the semiconductor device layer 220, the chip wiring layer 230, a bonding pad 240fa, the bonding pad 240b, the bonding insulating film 250f, the bonding insulating film 250b, the gold layer 260, and the through-via 270.

In an embodiment, the semiconductor chip 100D and the semiconductor chip 200C are of different types. For example, the semiconductor chip 100D is a memory semiconductor chip, and the semiconductor chip 200C is a logic semiconductor chip. The memory semiconductor chip may be, for example, a volatile memory such as a DRAM (dynamic random access memory) or an SRAM (static random access memory). Alternatively, the memory semiconductor chip may be a non-volatile memory such as a flash memory, a PRAM (phase-change random access memory), an MRAM (magnetoresistive random access memory), an FeRAM (ferroelectric random access memory), or an RRAM (resistive random access memory). The logic semiconductor chip is, for example, one of an application processor (AP) such as CPU (Central Processing Unit), a GPU (Graphic Processing Unit), an FPGA (Field-Programmable Gate Array), a digital signal processor, a cryptographic processor, a microprocessor, a microcontroller, or an ASIC (Application-Specific IC), etc. However, embodiments of the present disclosure are not necessarily limited thereto.

Alternatively, in an embodiment, each of the semiconductor chip 100D and the semiconductor chip 200C is a memory semiconductor chip. The memory semiconductor chip may be, for example, a volatile memory such as DRAM (dynamic random access memory) or SRAM (static random access memory). Alternatively, the memory semiconductor chip may be a non-volatile memory such as a flash memory, a PRAM (phase-change random access memory), an MRAM (magnetoresistive random access memory), an FeRAM (ferroelectric random access memory), or an RRAM (resistive random access memory). The semiconductor chip 200C may be, for example, a buffer semiconductor chip.

When the face surface 100f of the semiconductor chip 100D and the back surface 200b of the semiconductor chip 200C are bonded to each other, the semiconductor chip 100D and the semiconductor chip 200C are bonded to each other in a hybrid bonding scheme by an annealing process. The bonding insulating film 150f and the bonding insulating film 250b directly contact and are bonded to each other by an annealing process. The bonding pad 140f and the bonding pad 240b are bonded to each other by a material, such as gold (Au), by an annealing process. When the semiconductor chip 100D and the semiconductor chip 200C are bonded to each other, the bonding pad 140f and the bonding pad 240b face each other, and a space between the dishing 140f-1 of the bonding pad 140f and the dishing 240b-1 of the bonding pad 240b is filled with a gold bonding layer formed by fusing the gold layer 160 and the gold layer 260 to each other.

In this way, when the semiconductor chip 100D and the semiconductor chip 200C are bonded to each other in a hybrid bonding scheme by an annealing process, the bonding pad 140f and the bonding pad 240b are not directly bonded to each other in a copper (Cu)-copper (Cu) bonding scheme, but the gold layer 160 and the gold layer 260 are directly bonded to each other such that the semiconductor chip 100D and the semiconductor chip 200C are bonded to each other by the gold (Au). As a result, a phenomenon in which a copper oxide forms on the upper surface of bonding pads 140f and 240b that include copper (Cu) is prevented, which suppresses deterioration of the bonding quality between the bonding pads 140f and 240b.

Further, gold (Au), which has a smaller thermal expansion coefficient than copper (Cu), is disposed on each of the dishing 140f-1 of the bonding pad 140f and the dishing 240b-1 of the bonding pad 240b, such that the semiconductor chip 100D and the semiconductor chip 200C are bonded to each other when the gold layers 160 and 260 are bonded to each other. Thus, a standard dimension of each of the dishing 140f-1 and the dishing 240b-1 respectively formed in the upper surfaces of the bonding pads 140f and 240b can be more easily managed. For example, the standard dimension of each of the dishing 140f-1 and the dishing 240b-1 refers to a target depth of each of the dishing 140f-1 and the dishing 240b-1.

The mold film 800 surrounds the semiconductor chip 100D and the semiconductor chip 200C and is disposed on the redistribution substrate 900. The mold film 800 covers the semiconductor chip 100D and the semiconductor chip 200C. The mold film 800 extends along an upper surface of the redistribution substrate 900, an upper surface and a sidewall of the semiconductor chip 100D, and a sidewall of the semiconductor chip 200A. For example, the semiconductor chip 100D and the semiconductor chip 200C are covered by one mold film 800. FIG. 6 shows that the mold film 800 covers the back surface 100b of the semiconductor chip 100D. However, embodiments of the present disclosure are not necessarily limited thereto. In some further embodiments, a surface of the mold film 800 is coplanar with the back surface 100b of the semiconductor chip 100D.

The mold film 800 includes an insulating polymeric material, such as an EMC (epoxy molding compound). The mold film 800 also includes at least one of a thermosetting resin such as epoxy resin, a thermoplastic resin such as polyimide, or a core material such as a glass fiber, a glass cloth, or a glass fabric, along with an inorganic filler impregnated with a resin, such as prepreg, ABF (Ajinomoto Build-up Film), FR-4, or BT (Bismaleimide Triazine).

The inorganic filler includes at least one of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) or calcium zirconate (CaZrO₃). However, the material of the filler is not necessarily limited thereto, and in some embodiments includes a metal and/or an organic material.

The redistribution substrate 900 includes a redistribution layer 910, a substrate bonding layer 920 and a passivation layer 930. The semiconductor chip 100D and the semiconductor chip 200C are disposed on the redistribution substrate 900. The face surface 200f of the semiconductor chip 200C is bonded to the redistribution substrate 900.

The redistribution layer 910 includes, for example, a redistribution insulating film 911 and a redistribution pattern 912 disposed in the redistribution insulating film 911. The redistribution pattern 912 includes a wiring stack that has a multilayer structure and a via that connects the layers of the wiring stack to each other. The arrangement, the number of layers, and the number of the redistribution patterns 912 are illustrative, and embodiments of the present disclosure are not necessarily limited thereto.

The substrate bonding layer 920 is disposed on the redistribution layer 910. The substrate bonding layer 920 is disposed on an upper surface of the redistribution layer 910. The substrate bonding layer 920 includes, for example, a substrate bonding insulating film 921 and a substrate bonding pad 922 disposed in the substrate bonding insulating film 921. The substrate bonding pad 922 contacts the topmost redistribution pattern 912 of the redistribution patterns 912. Accordingly, the substrate bonding pad 922 is electrically connected to the redistribution layer 910.

The substrate bonding pad 922 includes, but is not necessarily limited to, a metal, such as copper (Cu), aluminum (Al), or tungsten (W). The substrate bonding insulating film 921 includes at least one insulating material, such as SiO, SiN, SiCN, SiOC, SiON, or SiOCN. However, embodiments of the present disclosure are not necessarily limited thereto.

The substrate bonding insulating film 921 and the substrate bonding pad 922 of the substrate bonding layer 920 are bonded to the bonding insulating film 250f and the bonding pad 240fa, respectively. The semiconductor chip 200C is electrically connected to the redistribution substrate 900.

The substrate bonding insulating film 921 and the substrate bonding pad 922 of the substrate bonding layer 920 are respectively bonded to the bonding insulating film 250f and the bonding pad 240fa in a hybrid bonding scheme. For example, the substrate bonding pad 922 is attached to the bonding pad 240fa while the substrate bonding insulating film 921 is attached to the bonding insulating film 250f. For example, the substrate bonding pad 922 and the bonding pad 240fa are bonded to each other in a copper (Cu)-copper (Cu) bonding scheme, while the substrate bonding insulating film 921 and the bonding insulating film 250f are bonded to each other in a dielectric-dielectric bonding scheme.

Although FIG. 6 shows that the substrate bonding pad 922 and the bonding pad 240fa directly contact and are bonded to each other, embodiments of the present disclosure are not necessarily limited thereto. For example, in some embodiments of the present disclosure, a dishing is inwardly recessed from an upper surface of each of the substrate bonding pad 922 and the bonding pad 240fa, and a gold layer is formed that fills at least a portion of each dishing. Accordingly, when the redistribution substrate 900 and the semiconductor chip 200C are bonded to each other, the substrate bonding pad 922 and the bonding pad 240fa are bonded to each other.

The passivation layer 930 is disposed on the redistribution layer 910. The passivation layer 930 is disposed on a lower surface of the redistribution layer 910. For example, the passivation layer 930 does not cover at least a portion of the bottommost redistribution pattern 912 of the redistribution patterns 912.

A connection terminal 940 is disposed on the redistribution substrate 900. The connection terminal 940 is disposed on, for example, the portion of the redistribution pattern 912 not covered with the passivation layer 930. Accordingly, the connection terminal 940 is electrically connected to the redistribution substrate 900. Thus, the semiconductor chip 100D and the semiconductor chip 200C can be electrically connected to an external device, such as a panel of an electronic device, via the connection terminal 940.

The connection terminal 940 includes, for example, one of a solder ball, a bump, or a UBM (under bump metallurgy), etc. The connection terminal 940 includes a metal such as tin (Sn). However, embodiments of the present disclosure are not necessarily limited thereto.

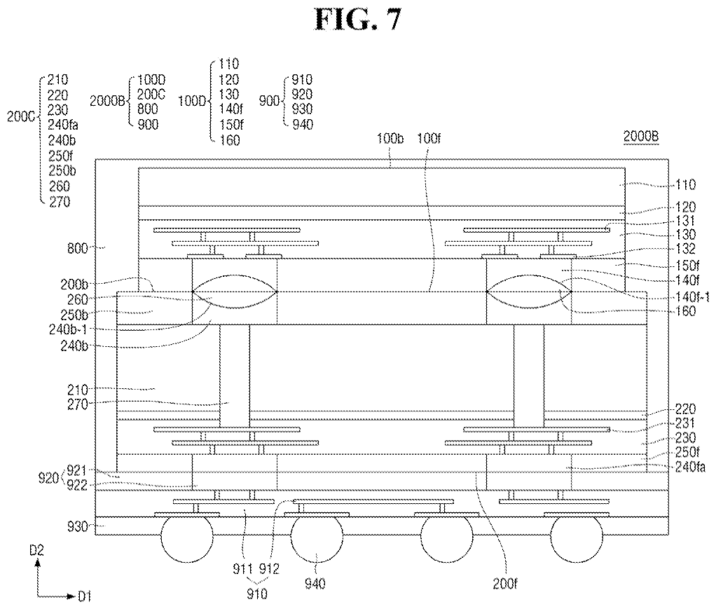

FIG. 7 illustrates a semiconductor package according to some further embodiments. Hereinafter, descriptions that duplicate the above descriptions are omitted, and the following descriptions focus on differences.

Referring to FIG. 7, unlike FIG. 6, in an embodiment, a semiconductor package 2000B is implemented with a small top die structure in which the semiconductor chips are bonded to each other in a hybrid bonding scheme such that a length in a first direction D1 of the upper semiconductor chip 100D is less than a length in the first direction D1 of the lower semiconductor chip 200C. Accordingly, the mold film 800 covers a portion of the back surface 200b of the lower semiconductor chip 200C.

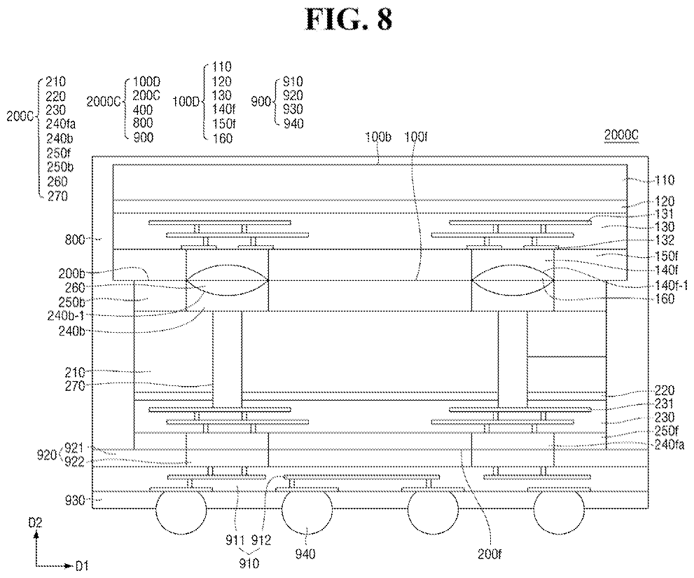

FIG. 8 illustrates a semiconductor package according to some still further embodiments. Hereinafter, descriptions that duplicate the above descriptions are omitted, and the following descriptions focus on differences.

Referring to FIG. 8, in an embodiment, unlike FIGS. 6 and 7, a semiconductor package 2000C is implemented in a large top die structure in which the semiconductor chips are bonded to each other in a hybrid bonding scheme such that a length in the first direction D1 of the upper semiconductor chip 100D is greater than a length in the first direction D1 of the lower semiconductor chip 200C. Accordingly, the mold film 800 covers a portion of the face surface 100f of the semiconductor chip 100D.

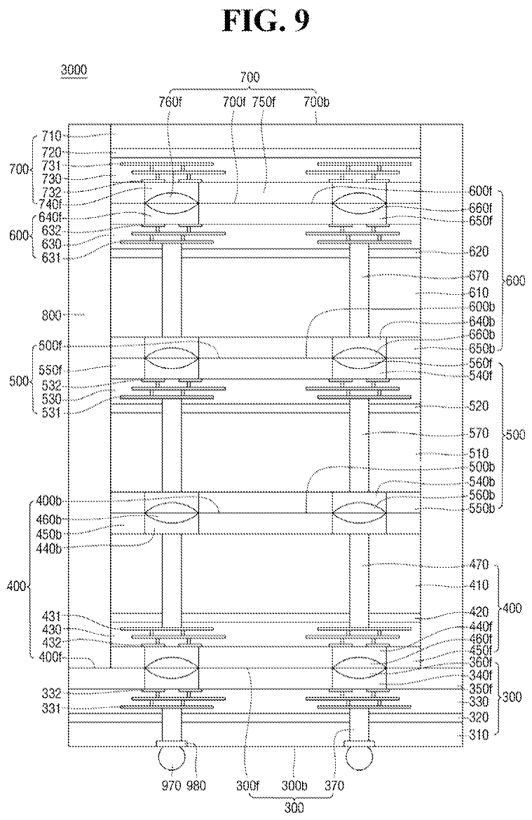

FIG. 9 illustrates a semiconductor package according to some still further embodiments. Hereinafter, descriptions that duplicate the above descriptions are omitted, and the following descriptions focus on differences.

Referring to FIG. 9, a semiconductor package 3000 according to some still further embodiments includes semiconductor chips 300, 400, 500, 600, and 700, the mold film 800, a connection structure 970, and a connection pad 980. The semiconductor chip 300 includes a substrate 310, a semiconductor device layer 320, a chip wiring layer 330, a bonding pad 340f, a bonding insulating film 350f, a gold layer 360f, and a through-via 370.

The semiconductor chip 400 includes a substrate 410, a semiconductor device layer 420, a chip wiring layer 430, bonding pads 440f and 440b, bonding insulating films 450f and 450b, gold layers 460f and 460b, and a through-via 470. In the semiconductor chip 400, the bonding pad 440f and the bonding pad 440b are electrically connected to each other by the through-via 470. The bonding pad 440f and the bonding pad 440b are opposite to each other with the through-via 470 interposed therebetween. The bonding pad 440b is directly connected to the through-via 470, and the bonding pad 440f is electrically connected to the through-via 470 by the chip wiring layer 430, the wiring pattern 431, and the connective pad 432.

The semiconductor chip 500 includes a substrate 510, a semiconductor device layer 520, a chip wiring layer 530, bonding pads 540f and 540b, bonding insulating films 550f and 550b, gold layers 560f and 560b, and a through-via 570.

The semiconductor chip 600 includes a substrate 610, a semiconductor device layer 620, a chip wiring layer 630, bonding pads 640f and 640b, bonding insulating films 650f and 650b, gold layers 660f and 660b, and a through-via 670.

The semiconductor chip 700 includes a substrate 710, a semiconductor device layer 720, a chip wiring layer 730, bonding pads 740f, a bonding insulating film 750f, and a gold layer 760f.

Each of the semiconductor chips 300, 400, 500, 600, and 700 is a memory semiconductor chip. The memory semiconductor chip may be, for example, a volatile memory such as a DRAM (dynamic random access memory) or an SRAM (static random access memory). Alternatively, the memory semiconductor chip may be a non-volatile memory such as a flash memory, a PRAM (phase-change random access memory), an MRAM (magnetoresistive random access memory), an FeRAM (ferroelectric random access memory), or an RRAM (resistive random access memory). The semiconductor chip 300 may be, for example, a buffer semiconductor chip.

Alternatively, the semiconductor chip 300 may be a logic semiconductor chip, and each of the semiconductor chips 400, 500, 600, and 700 may be a memory semiconductor chip. The semiconductor chip 300 may be a controller semiconductor chip that controls operations, such as input/output, of the semiconductor chip 400 that is electrically connected to the semiconductor chip 300.

The semiconductor chip 300 and the semiconductor chip 400 are bonded to each other in a hybrid bonding scheme. For example, a face surface 300f of the semiconductor chip 300 and a face surface 400f of the semiconductor chip 400 are bonded to each other and face each other. For example, the bonding insulating film 350f and the bonding insulating film 450f are in direct contact with each other such that the bonding pad 340f and the bonding pad 440f face each other, and then, the gold layer 360f and the gold layer 460f are directly bonded to each other. Thus, the semiconductor chip 300 and the semiconductor chip 400 are bonded to each other in a hybrid bonding scheme.

The connection pad 980 is disposed on a lower surface of the semiconductor chip 300. The connection pad 980 includes, for example, at least one of aluminum (Al), copper (Cu), nickel Ni, tungsten (W), platinum (Pt), gold (Au), or combinations thereof. However, embodiments of the present disclosure are not necessarily limited thereto. The connection pad 980 directly contacts and is electrically connected to the through-via 370.

The connection structure 970 is disposed on the connection pad 980. The connection structure 970 is electrically connected to the connection pad 980. The connection structure 970 may have various shapes, such as a pillar structure, a ball structure, a solder layer, etc.

The semiconductor chip 400 and the semiconductor chip 500 are bonded to each other in a hybrid bonding scheme. For example, a back surface 400b of the semiconductor chip 400 and a back surface 500b of the semiconductor chip 500 are bonded to each other and face each other. For example, the bonding insulating film 450b and the bonding insulating film 550b directly contact each other so that the bonding pad 440b and the bonding pad 540b face each other, and then the gold layer 460b and the gold layer 560b are directly bonded to each other. Thus, the semiconductor chip 400 and the semiconductor chip 500 are bonded to each other in a hybrid bonding scheme.

The semiconductor chip 500 and the semiconductor chip 600 are bonded to each other in a hybrid bonding scheme. For example, a face surface 500f of the semiconductor chip 500 and a back surface 600b of the semiconductor chip 600 are bonded to each other and face each other. For example, the bonding insulating film 550f and the bonding insulating film 650b directly contact each other such that the bonding pad 540f and the bonding pad 640b face each other, and then, the gold layer 560f and the gold layer 660b are directly bonded to each other. Thus, the semiconductor chip 500 and the semiconductor chip 600 are bonded to each other in a hybrid bonding scheme.

The semiconductor chip 600 and the semiconductor chip 700 are bonded to each other in a hybrid bonding scheme. For example, a face surface 600f of the semiconductor chip 600 and a face surface 700f of the semiconductor chip 700 are bonded to each other and face each other. For example, the bonding insulating film 650f and the bonding insulating film 750f directly contact each other so that the bonding pad 640f and the bonding pad 740f face each other, and then, the gold layer 660f and the gold layer 760f are directly bonded to each other. Thus, the semiconductor chip 600 and the semiconductor chip 700 are bonded to each other in a hybrid bonding scheme.

In this way, in the semiconductor package 3000 that includes a plurality of stacked semiconductor chips 300, 400, 500, 600, and 700, when the semiconductor chips 300, 400, 500, 600, and 700 are bonded to each other in a hybrid copper bonding scheme, the gold layers between the bonding pads directly contact each other and fuse into each other, such that bonding quality of the hybrid copper bonding is increased.

The mold layer 800 is disposed on an upper surface of the semiconductor chip 300. The mold layer 800 covers sidewalls of the semiconductor chips 400, 500, 600, and 700. FIG. 9 shows that an upper surface of the mold layer 800 is coplanar with an upper surface of the semiconductor chip 700. However, embodiments of the present disclosure are not necessarily limited thereto. In some further embodiments, the mold layer 800 covers the upper surface of the semiconductor chip 700.

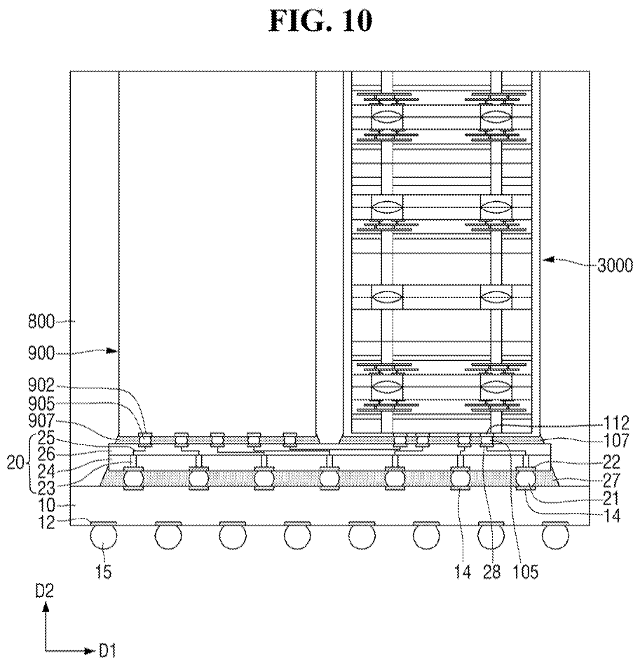

FIG. 10 illustrates a semiconductor package according to some still further embodiments.

Referring to FIG. 10, the semiconductor package according to some still further embodiments further includes a substrate 10, an interposer 20, and a semiconductor chip 900.

The substrate 10 is a substrate for a package. For example, the substrate 10 may be a printed circuit board (PCB) or a ceramic substrate. However, embodiments of the present disclosure are not necessarily limited thereto.

A first substrate pad 12 is disposed on a lower surface of the substrate 10. A second substrate pad 14 is disposed on an upper surface of the substrate 10. Each of the first substrate pad 12 and the second substrate pad 14 includes, for example, a metal such as copper (Cu) or aluminum (Al). However, embodiments of the present disclosure are not necessarily limited thereto.

The substrate 10 can be mounted on a main board of an electronic device. For example, a third connection terminal 15 connected to the substrate 10 is formed. The substrate 10 is mounted on the main board of an electronic device by the third connection terminal 15.

An interposer 20 is disposed on the upper surface of the substrate 10. The interposer 20 may be, for example, a silicon interposer. However, embodiments of the present disclosure are not necessarily limited thereto. The interposer 20 facilitates connection between the substrate 10 and the semiconductor chips 300, 400, 500, 600, and 700 of FIG. 9, and the semiconductor chip 900, and prevents warpage of the semiconductor package. The interposer 20 is mounted on the upper surface of the substrate 10. For example, a fourth connection terminal 21 is formed between the substrate 10 and the interposer 20. The fourth connection terminal 21 connects the second substrate pad 14 and a first interposer pad 22 to each other. Accordingly, the substrate 10 and the interposer 20 are electrically connected to each other.

A first underfill material layer 27 is disposed between the substrate 10 and the interposer 20. The first underfill material layer 27 fills a space between the substrate 10 and the interposer 20. Further, the first underfill material layer 27 surrounds the fourth connection terminal 21. The first underfill material layer 27 fixes the interposer 20 onto the substrate 10 to prevent damage to the interposer 20. The first underfill material layer 27 includes, but is not necessarily limited to, an insulating polymer material such as EMC (epoxy molding compound).

The interposer 20 includes the first interposer pad 22 and a second interposer pad 28. The first interposer pad 22 and the second interposer pad 28 are used to electrically connect the interposer 20 with other components. For example, the first interposer pad 22 is exposed at a lower surface of the interposer 20, and the second interposer pad 28 is exposed at an upper surface of the interposer 20. Each of the first interposer pad 22 and the second interposer pad 28 includes, for example, a metal such as copper (Cu) or aluminum (Al). However, embodiments of the present disclosure are not necessarily limited thereto. Wiring patterns that electrically connect the first interposer pad 22 and the second interposer pad 28 to each other are formed in the interposer 20.

The interposer 20 includes a through-via 23, a semiconductor film 24, a redistribution pattern 25, and an interlayer insulating film 26.

The semiconductor film 24 may be, for example, a silicon film. However, embodiments of the present disclosure are not necessarily limited thereto. The through-via 23 extends through the semiconductor film 24. For example, the through-via 23 extends from an upper surface of the semiconductor film 24 and is connected to the first interposer pad 22.

The interlayer insulating film 26 covers the upper surface of the semiconductor film 24. The interlayer insulating film 26 includes, for example, at least one of silicon oxide, silicon nitride, silicon oxynitride, or a low-k material with a lower dielectric constant than silicon oxide. However, embodiments of the present disclosure are not necessarily limited thereto. The redistribution pattern 25 is formed in the interlayer insulating film 26. The redistribution pattern 25 electrically connects the through-via 23 and the second interposer pad 28 to each other.

The semiconductor chip 900 and the semiconductor chips 300, 400, 500, 600, and 700 of FIG. 9 are sequentially stacked and mounted on the interposer 20. For example, a first connection terminal 105 is formed between the interposer 20 and the semiconductor chip 300 of FIG. 9. The first connection terminal 105 connects some of a plurality of second interposer pads 28 to a first connection pad 112. Accordingly, the interposer 20 and the semiconductor chip 300 of FIG. 9 are electrically connected to each other. Further, for example, a second connection terminal 905 is formed between the interposer 20 and the semiconductor chip 900. The second connection terminal 905 connects other second interposer pads 28 to a second connection pad 902. Accordingly, the interposer 20 and the semiconductor chip 900 are electrically connected to each other.

A portion of the redistribution pattern 25 electrically connects the first connection terminal 105 and the second connection terminal 905 to each other. For example, a portion of the redistribution pattern 25 connects the second interposer pad 28 connected to the first connection terminal 105 to the second connection pad 902 connected to the second connection terminal 905. Accordingly, the semiconductor chip 300 of FIG. 9 and the semiconductor chip 900 are electrically connected to each other.

A second underfill material layer 107 is disposed between the semiconductor chip 300 of FIG. 9 and the interposer 20. The second underfill material layer 107 fills a space between the semiconductor chip 300 of FIG. 9 and the interposer 20. Further, the second underfill material layer 107 surrounds the first connection terminal 105. A third underfill material layer 907 is disposed between the semiconductor chip 900 and the interposer 20. The third underfill material layer 907 fills a space between the semiconductor chip 900 and the interposer 20. Further, the third underfill material layer 907 surrounds the second connection terminal 905.

Each of the first connection terminal 105, the second connection terminal 905, the third connection terminal 15, and the fourth connection terminal 21 has one of various shapes, such as a pillar structure, a ball structure, or a solder layer. The first connection terminal 105, the second connection terminal 905, the third connection terminal 15, and the fourth connection terminal 21 may have, for example, the same size or different sizes. For example, the sizes of the first connection terminal 105 and the second connection terminal 905 are substantially the same, and the sizes of each of the first connection terminal 105 and the second connection terminal 905 are smaller than the sizes of each of the third connection terminal 15 and the fourth connection terminal 21. The size of the fourth connection terminal 21 is smaller than that of the third connection terminal 15.

The semiconductor chip 900 may be an integrated circuit (IC) in which hundreds to millions of semiconductor devices are integrated into one chip. For example, the semiconductor chip 900 is one of an application processor (AP) such as CPU (Central Processing Unit), a GPU (Graphic Processing Unit), an FPGA (Field-Programmable Gate Array), a digital signal processor, an encryption processor, a microprocessor, a microcontroller, etc. Embodiments of the present disclosure are not necessarily limited thereto. For example, the semiconductor chip 900 is one of a logic chip such as an ADC (Analog-Digital Converter) or an ASIC (Application-Specific IC), or a memory chip such as a volatile memory such as a DRAM or a non-volatile memory such as a ROM or a flash memory. Further, the semiconductor chip 900 may include a combination thereof.

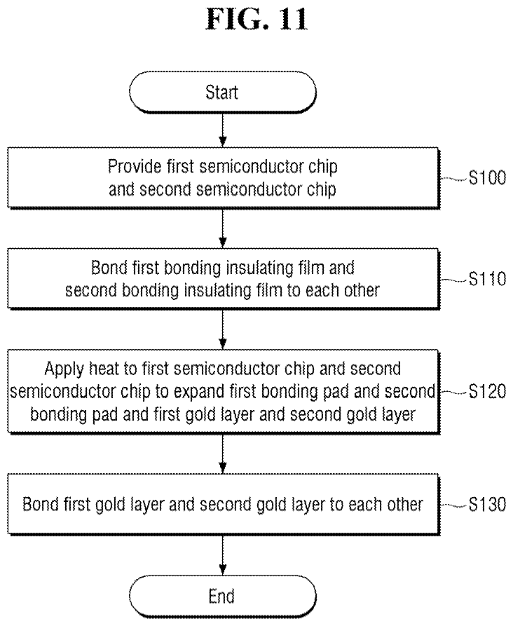

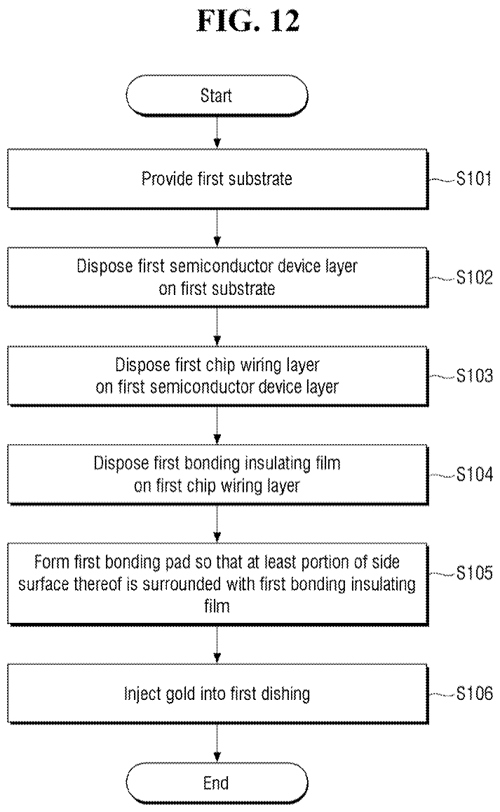

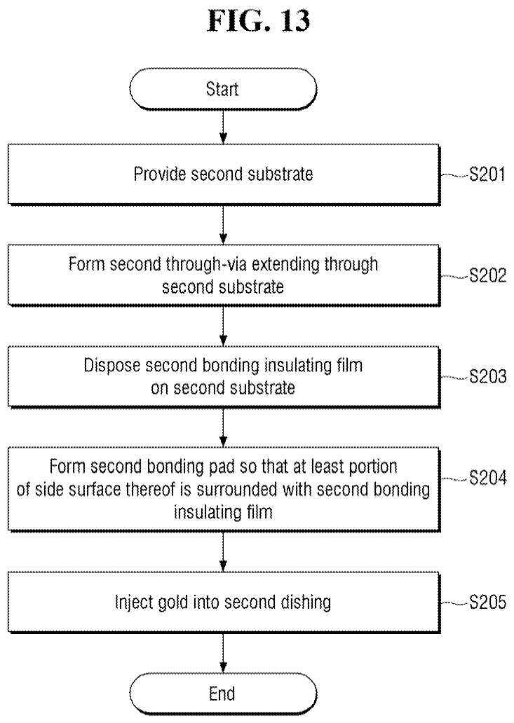

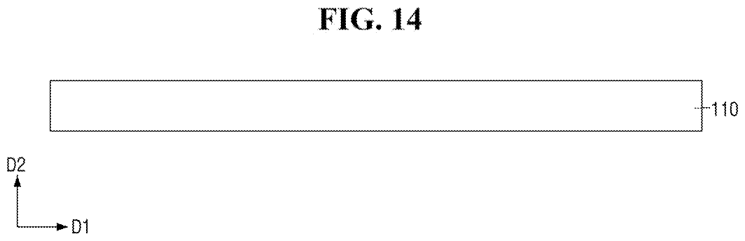

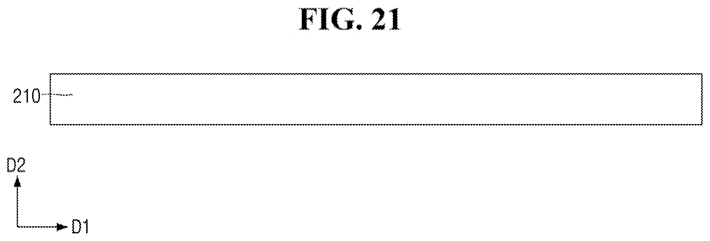

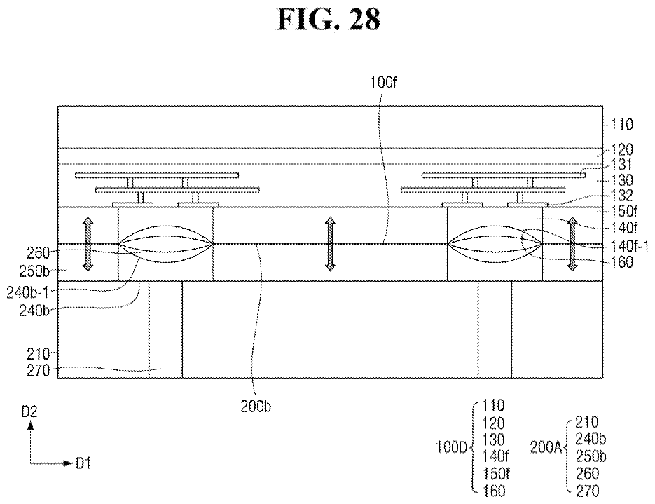

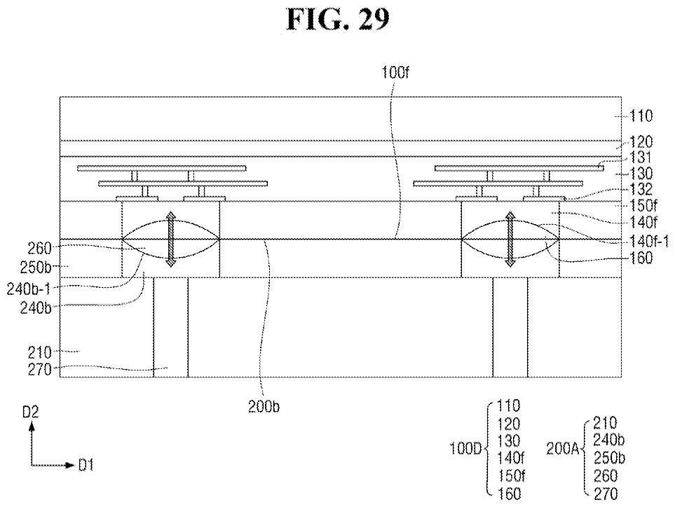

FIG. 11 is a flowchart of a method for manufacturing a semiconductor package according to some embodiments. FIG. 12 is a flowchart of a process of providing a first semiconductor chip of FIG. 11. FIG. 13 is a flowchart of a process of providing a second semiconductor chip of FIG. 11. FIG. 14 to FIG. 20 illustrate intermediate structures of intermediate steps of a process of providing a first semiconductor chip of FIG. 12. FIG. 21 to FIG. 27 illustrate intermediate structures of intermediate steps of a process of providing a second semiconductor chip of FIG. 13. FIG. 28 and FIG. 29 illustrate intermediate structures of intermediate steps of a method for manufacturing a semiconductor package of FIG. 11. Hereinafter, a method for manufacturing a semiconductor package according to some embodiments will be described with reference to FIG. 11 to FIG. 29.

Referring to FIG. 11, the first semiconductor chip and the second semiconductor chip are provided in S100.

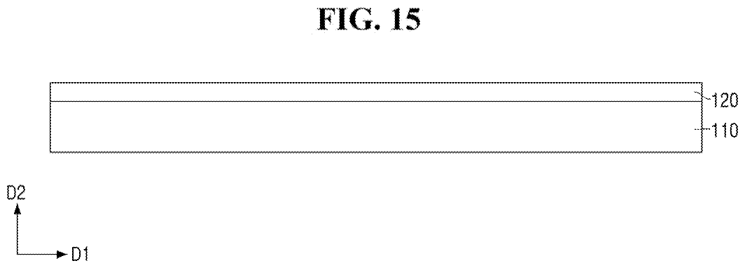

For example, the first semiconductor chip is identical to the semiconductor chip 100D in FIG. 6, and the second semiconductor chip is identical to the semiconductor chip 200A in FIG. 1. Referring to FIG. 12 and FIG. 14, the substrate 110 of the first semiconductor chip is provided in S101. Referring to FIG. 12 and FIG. 15, the semiconductor device layer 120 is disposed on the substrate 110 in S102.

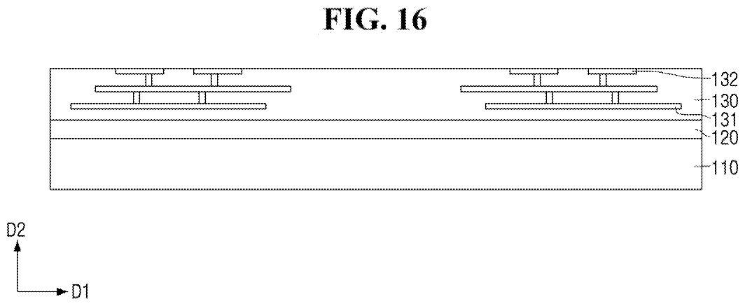

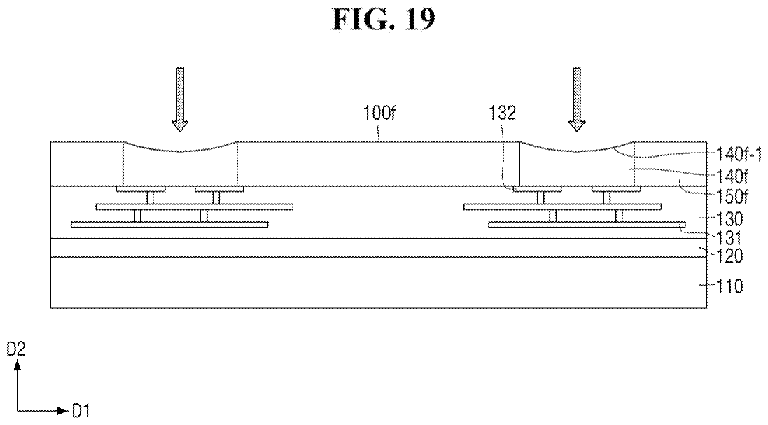

Referring to FIG. 12 and FIG. 16, the chip wiring layer 130 is disposed on the semiconductor device layer 120 in S103. The chip wiring layer 130 contains a wiring pattern 131 therein. At least one connective pad 132 is formed on the uppermost portion of the chip wiring layer 130. The connective pad 132 will directly contact the bonding pad 140f of FIG. 19 formed in a subsequent process step. Further, in some embodiments, an additional through-via 170 of FIG. 1 that penetrates through the substrate 110 is formed.

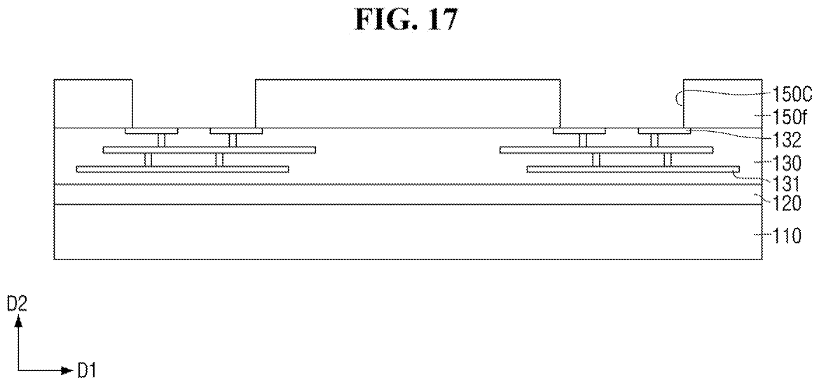

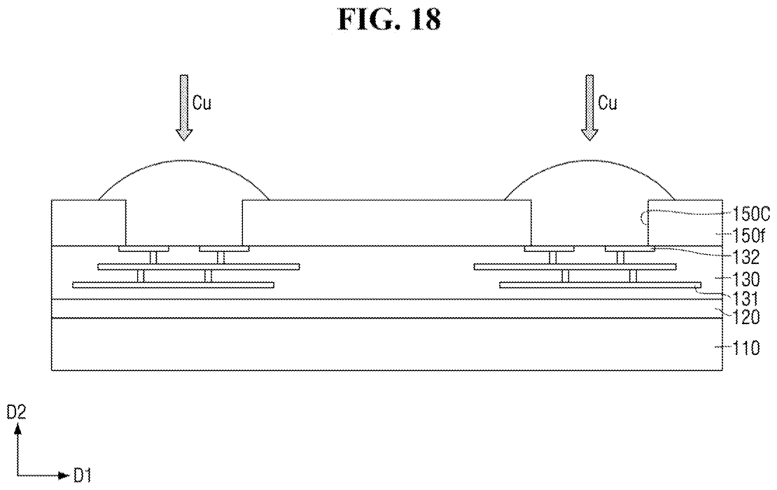

Referring to FIG. 12 and FIG. 17, the bonding insulating film 150f is disposed on the chip wiring layer 130 in S104. For example, the bonding insulating film 150f includes a cavity 150C formed therein into which copper (Cu) is injected to form a bonding pad in a later process step. Referring to FIG. 12, FIG. 18, and FIG. 19, the bonding pad 140f is formed 150f in S105 so that at least a portion of a side surface thereof is surrounded by the bonding insulating film. As shown in FIG. 18, heat that forms a bonding pad is applied to the cavity 150C such that copper (Cu) in a liquid state is injected into the cavity. For example, copper (Cu) is injected to overflow an upper surface of the bonding insulating film 150f. The copper (Cu) injected into the cavity 150C cools down and forms a solid. As shown in FIG. 19, a CMP process is performed on an upper surface of the bonding pad 140f to form the dishing 140f-1 that is recessed from the upper surface of the bonding pad 140f.

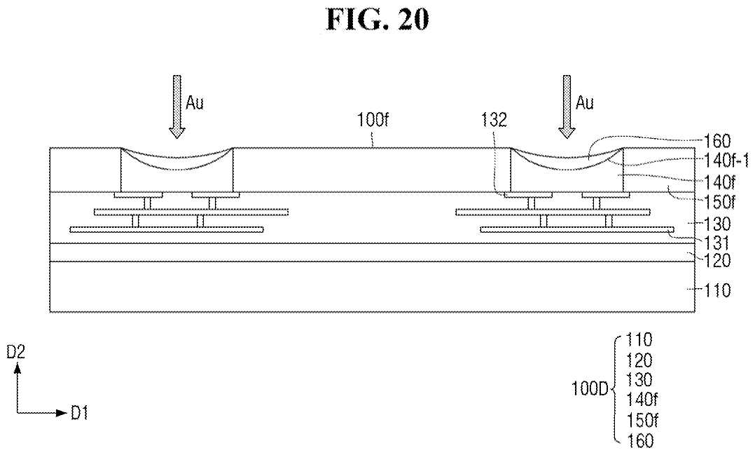

Referring to FIG. 12 and FIG. 20, gold (Au) is injected into the dishing 140f-1 in S106. The gold (Au) is injected using a sputtering process to fill at least a portion of the dishing 140f-1 such that the gold layer 160 is formed in the dishing 140f-1. The finally formed semiconductor chip 100D has the exposed face surface 100f composed of the bonding insulating film 150f and the gold layer 160.

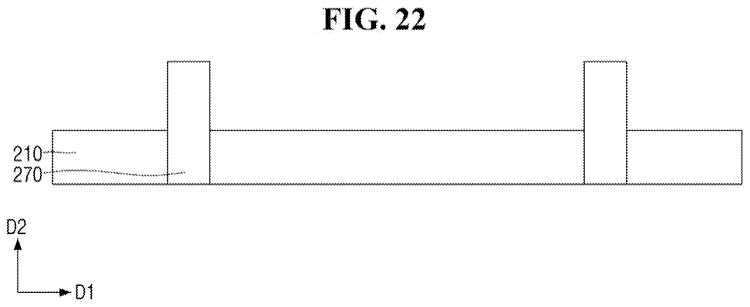

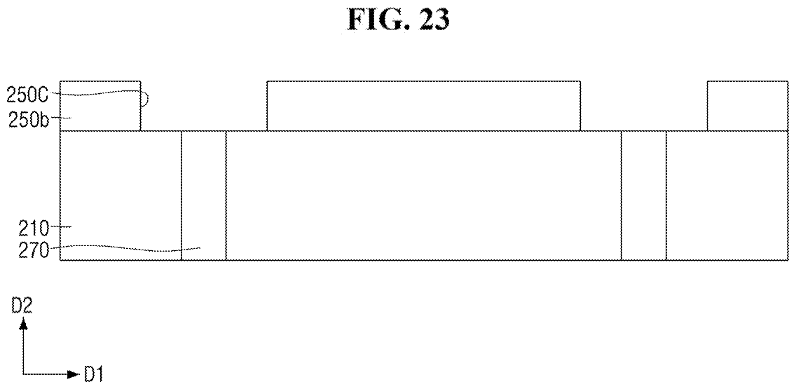

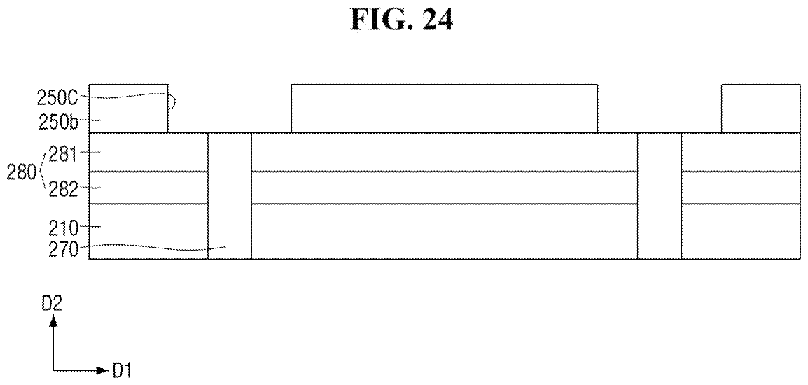

Referring to FIG. 13 and FIG. 21, the substrate 210 of the second semiconductor chip is provided in S201. Referring to FIG. 13 and FIG. 22, the through-via 270 that penetrates through the substrate 210 is formed in S202. Referring to FIG. 13 and FIG. 23, the bonding insulating film 250b is disposed on the substrate 210 in S203. For example, the bonding insulating film 250b includes a cavity 250C formed therein into which copper (Cu) is injected to form a bonding pad in a later process step. In some embodiments, as shown in FIG. 24, the buffer insulating film 280 is formed between the bonding insulating film 250b and the substrate 210. For example, the oxide film 282, the nitride film 281, and the bonding insulating film 250b are sequentially stacked on the substrate 210. Further, the buffer insulating film 280 surrounds a portion of the side surface of the through-via 270 and protects the through-via 270.

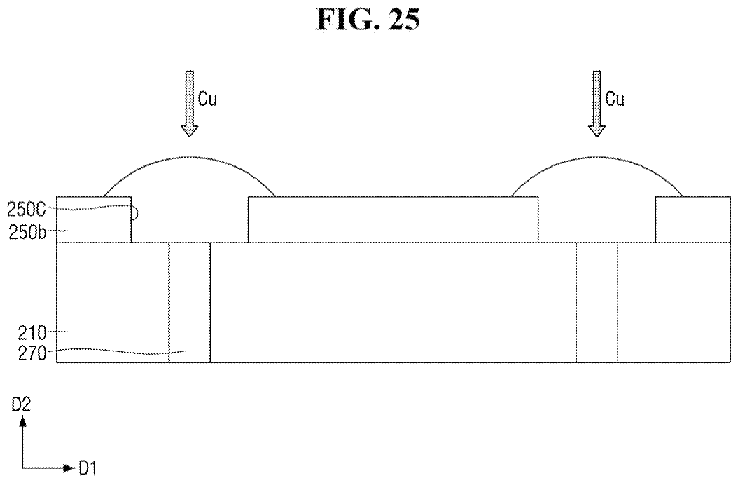

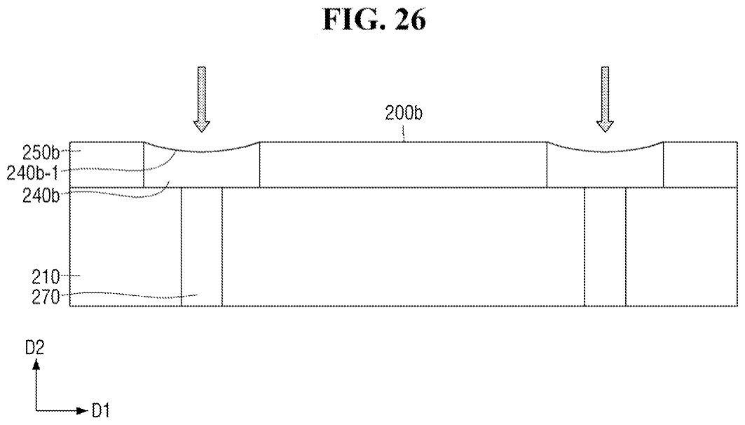

Referring to FIG. 13, FIG. 25, and FIG. 26, the bonding pad 240b is formed in S204 so that at least a portion of the side surface thereof is surrounded by the bonding insulating film 250b. As shown in FIG. 25, heat that forms a bonding pad is applied to the cavity 250C such that copper (Cu) in a liquid state is injected into the cavity. For example, the copper (Cu) is injected to overflow an upper surface of the bonding insulating film 250b. Thereafter, the copper (Cu) injected into the cavity 250C cools down and forms a solid. As shown in FIG. 26, a CMP process is performed on an upper surface of the bonding pad 240b to form the dishing 240b-1 that is recessed from the upper surface of the bonding pad 240b.

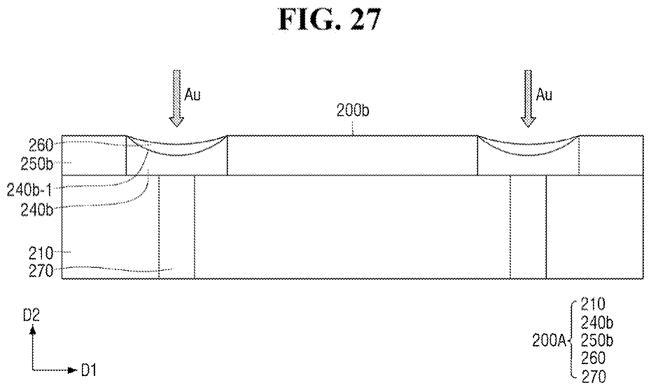

Referring to FIG. 13 and FIG. 27, the gold (Au) is injected into the dishing 240b-1 in S205. The gold (Au) is injected via a sputtering process to fill at least a portion of the dishing 240b-1 such that the gold layer 260 is formed in the dishing 240b-1. The finally formed semiconductor chip 200A has the exposed back surface 200b composed of the bonding insulating film 250b and the gold layer 260.

Referring to FIG. 11 and FIG. 28, the bonding insulating film 150f and the bonding insulating film 250b are bonded to each other using an annealing process in S110. The semiconductor chip 100D and the semiconductor chip 200A are oriented so that the face surface 100f of the semiconductor chip 100D and the back surface 200b of the semiconductor chip 200A face each other. The bonding insulating film 150f of the semiconductor chip 100D and the bonding insulating film 250b of the semiconductor chip 200A are in direct contact with each other and are bonded to each other.

Referring to FIG. 11 and FIG. 29, heat is applied to the semiconductor chip 100D and the semiconductor chip 200A in S120 to expand the bonding pads 140f and 240b and the gold layers 160 and 260. The gold layer 160 and the gold layer 260 are bonded to each other in S130. Thus, when the semiconductor chip 100D and the semiconductor chip 200A are bonded to each other so that the bonding pad 140f and the bonding pad 240b face each other, the gold layers 160 and 260 between the dishing 140f-1 of the bonding pad 140f and the dishing 240b-1 of the bonding pad 240b are bonded to each other, such that bonding quality of hybrid copper bonding is increased.

Embodiments of the present disclosure have been described above with reference to the accompanying drawings, but embodiments of the present disclosure are not necessarily limited thereto and can be implemented in various different forms. It will be understood that embodiments of the present disclosure can be implemented in other specific forms without changing the technical spirit or gist of the present disclosure. Therefore, it should be understood that embodiments set forth herein are illustrative in all respects and not limiting.

What is claimed is:

1. A semiconductor package, comprising:
a first semiconductor chip;
a second semiconductor chip; and
a gold bonding layer,
wherein the first semiconductor chip includes:
a first substrate;
a first semiconductor device layer disposed on the first substrate;
a first chip wiring layer disposed on the first semiconductor device layer; and
a first bonding pad directly connected to the first chip wiring layer and that includes a first dishing formed therein;
wherein the second semiconductor chip includes:
a second substrate;
a first through-via that penetrates through the second substrate; and
a second bonding pad directly connected to the first through-via and that includes a second dishing formed therein,
wherein the first semiconductor chip and the second semiconductor chip are bonded to each other so that the first bonding pad and the second bonding pad face each other; and
the gold bonding layer fills the first dishing of the first bonding pad and the second dishing of the second bonding pad.

2. The semiconductor package of claim 1, wherein the first semiconductor chip further includes a first bonding insulating film disposed on the first chip wiring layer and that surrounds at least a portion of a side surface of the first bonding pad.

3. The semiconductor package of claim 2, further comprising a buffer insulating film formed on a back surface of the second substrate.

4. The semiconductor package of claim 3, wherein the first through-via penetrates through the second substrate and the buffer insulating film.

5. The semiconductor package of claim 3, wherein the second bonding pad directly contacts the buffer insulating film and the first through-via.

6. The semiconductor package of claim 3, wherein the second semiconductor chip further includes a second bonding insulating film disposed on the buffer insulating film and that surrounds at least a portion of a side surface of the second bonding pad.

7. The semiconductor package of claim 6,
wherein the buffer insulating film includes a first oxide film and a nitride film that are sequentially stacked,
wherein the second bonding insulating film includes a second oxide film formed on the nitride film.

8. The semiconductor package of claim 1,
wherein the first chip wiring layer includes at least one connective pad disposed on an uppermost layer thereof,
wherein the first bonding pad directly contacts the connective pad.

9. The semiconductor package of claim 1, wherein the first semiconductor chip further includes a second through-via that penetrates through the first substrate and is connected to the first bonding pad.

10. The semiconductor package of claim 9, wherein the first semiconductor chip further includes a third bonding pad that is directly connected to the second through-via and opposite to the first bonding pad.

11. The semiconductor package of claim 10, wherein the third bonding pad has a third dishing formed therein, wherein at least a portion of the third dishing is filled with gold (Au).

12. The semiconductor package of claim 1, wherein the second semiconductor chip includes a fourth bonding pad connected to the first through-via and opposite to the second bonding pad.

13. The semiconductor package of claim 12, wherein the fourth bonding pad has a fourth dishing formed therein, and at least a portion of the fourth dishing is filled with gold (Au).

14. A semiconductor package, comprising:
a first semiconductor chip; and
a second semiconductor chip,
wherein the first semiconductor chip includes:
a first substrate;
a first semiconductor device layer disposed on the first substrate;
a first chip wiring layer disposed on the first semiconductor device layer;
a first bonding insulating film disposed on the first chip wiring layer;
a first bonding pad that includes a first dishing formed therein, wherein at least a portion of a side surface of the first bonding pad is surrounded by the first bonding insulating film;
a first gold layer that fills the first dishing; and
a first through-via that penetrates through the first substrate and is connected to the first bonding pad,
wherein the second semiconductor chip includes:
a second substrate;
a second bonding insulating film disposed on the second substrate;
a second bonding pad that includes a second dishing formed therein, wherein at least a portion of a side surface of the second bonding pad is surrounded by the second bonding insulating film;
a second gold layer that fills the second dishing; and
a second through-via that penetrates through the second substrate and is connected to the second bonding pad,
wherein the first semiconductor chip and the second semiconductor chip are bonded to each other so that the first bonding pad and the second bonding pad face each other, and
wherein the first gold layer and the second gold layer are bonded to each other.

15. The semiconductor package of claim 14, wherein the second bonding pad is directly connected to the second through-via.

16. The semiconductor package of claim 14, wherein the second semiconductor chip further includes:
a second semiconductor device layer disposed between the second substrate and the second bonding insulating film; and
a second chip wiring layer disposed between the second semiconductor device layer and the second bonding insulating film,
wherein the second bonding pad is directly connected to the second chip wiring layer.

17. A method for manufacturing a semiconductor package, wherein the method comprises:
providing a first semiconductor chip and a second semiconductor chip, wherein the first semiconductor chip includes a first bonding pad that includes a first dishing formed therein, a first bonding insulating film that surrounds at least a portion of a side surface of the first bonding pad, and a first gold layer that fills the first dishing, and the second semiconductor chip includes a second bonding pad that includes a second dishing formed therein, a second bonding insulating film that surrounds at least a portion of a side surface of the second bonding pad, and a second gold layer that fills the second dishing;
bonding the first bonding insulating film and the second bonding insulating film to each other;
applying heat to the first semiconductor chip and the second semiconductor chip so that the first bonding pad, the second bonding pad, the first gold layer and the second gold layer expand; and
bonding the first gold layer and the second gold layer to each other.

18. The method of claim 17, wherein providing the first semiconductor chip includes:
providing a first substrate;
disposing a first semiconductor device layer on the first substrate;
disposing a first chip wiring layer on the first semiconductor device layer;
disposing the first bonding insulating film on the first chip wiring layer;
forming the first bonding pad on the first chip wiring layer; and
injecting gold into the first dishing.

19. The method of claim 18, wherein providing the first semiconductor chip further includes forming a second through-via that penetrates through the first substrate and is connected to the first bonding pad.

20. The method of claim 17, wherein providing the second semiconductor chip includes:
providing a second substrate;
forming a first through-via that penetrates through the second substrate;
disposing the second bonding insulating film on the second substrate;
forming the second bonding pad that is directly connected to the first through-via; and
injecting gold into the second dishing.
